(19) United States
(12) Patent Application Publication
(10) Pub. No.: US 2026/0104096 A1
(43) Pub. Date: Apr. 16, 2026

(54) VALVE AND SUBSTRATE PROCESSING APPARATUS

(71) Applicant: Tokyo Electron Limited, Tokyo (JP)

(72) Inventor: Manabu HONMA, Oshu City (JP)

(21) Appl. No.: 19/234,767

(22) Filed: Jun. 11, 2025

(30) Foreign Application Priority Data
Jun. 18, 2024 (JP) 2024-098181

(51) Int. Cl. F16K 5/06; C23C 16/44

(52) U.S. Cl. CPC F16K 5/0605; C23C 16/4412; F16K 5/0663

(57) ABSTRACT

A valve includes: a housing having a flow path of fluid in the housing; and a valve body provided rotatably with respect to the housing, and configured to open and close the flow path, wherein the housing has a housing seal surface that surrounds the flow path, wherein the valve body has a valve body seal surface, which is formed on an outer periphery portion of the valve body and faces the housing seal surface when the valve body is located at a closing position for closing the flow path, and wherein the valve body seal surface faces a closing rotation direction of the valve body for closing the flow path, over an entire circumference of the outer periphery portion.

### CROSS-REFERENCE TO RELATED APPLICATION

This application is based upon and claims the benefit of priority from Japanese Patent Application No. 2024-098181, filed on Jun. 18, 2024, the entire contents of which are incorporated herein by reference.

### TECHNICAL FIELD

The present disclosure relates to a valve and a substrate processing apparatus.

### BACKGROUND

Patent Document 1 discloses a ball valve (fluid control valve) for controlling a flow rate of a fluid. This valve has a primary flow path, a seal assembly, and a ball element (valve body), which are provided in a housing. The ball element is provided rotatably in the housing, and closes the valve by being brought into contact with a main seal of the seal assembly as it rotates.

In this type of valve, since the ball element is significantly retracted from the primary flow path in an open state, a large flow rate of fluid can flow through the primary flow path. However, when the ball element rotates, an amount of sliding of the ball element against the seal assembly increases. Therefore, friction and the like accompanying the sliding may be easily generated.

### PRIOR ART DOCUMENT

### Patent Document

Patent Document 1: Japanese Patent Laid-open Publication No. 2005-521006

### SUMMARY

According to one embodiment of the present disclosure, a valve includes: a housing having a flow path of fluid in the housing; and a valve body provided rotatably with respect to the housing, and configured to open and close the flow path, wherein the housing has a housing seal surface that surrounds the flow path, wherein the valve body has a valve body seal surface, which is formed on an outer periphery portion of the valve body and faces the housing seal surface when the valve body is located at a closing position for closing the flow path, and wherein the valve body seal surface faces a closing rotation direction of the valve body for closing the flow path, over an entire circumference of the outer periphery portion.

### BRIEF DESCRIPTION OF DRAWINGS

The accompanying drawings, which are incorporated in and constitute a part of the specification, illustrate embodiments of the present disclosure, and together with the general description given above and the detailed description of the embodiments given below, serve to explain the principles of the present disclosure.

FIG. 1 is a diagram showing an example of a substrate processing apparatus to which a valve according to an embodiment is applied.

FIG. 2 is a perspective view showing the valve according to the embodiment.

FIG. 3A is a cross-sectional view of the valve in an X-Z axis direction, and FIG. 3B is a cross-sectional view of the valve in an X-Y axis direction.

FIG. 4 is a diagram showing an operation when a valve body closes a sealing tube.

FIG. 5A is a plan view of the valve body as viewed from a Z-axis positive direction, and FIG. 5B is a front view of the valve body as viewed from an X-axis negative direction.

FIG. 6A is a cross-sectional plan view of the valve in an open state, FIG. 6B is a cross-sectional plan view of the valve when an open degree thereof is being adjusted, and FIG. 6C is a cross-sectional plan view of the valve before it becomes closed.

FIG. 7A is an enlarged cross-sectional plan view showing a seal on a valve body seal surface at a rear end in a closing rotation direction, FIG. 7B is an enlarged cross-sectional plan view showing the seal of the valve body seal surface at a leading end in the closing rotation direction, and FIG. 7C is an enlarged cross-sectional plan view showing a seal of a valve body seal surface at a leading end in a closing rotation direction in another embodiment.

FIG. 8A is a schematic diagram of a valve according to a first modification, and FIG. 8B is a schematic diagram of a valve according to a second modification.

FIG. 9 is a schematic cross-sectional view of a sealing tube according to a third modification.

### DETAILED DESCRIPTION

Reference will now be made in detail to various embodiments, examples of which are illustrated in the accompanying drawings. In the following detailed description, numerous specific details are set forth in order to provide a thorough understanding of the present disclosure. However, it will be apparent to one of ordinary skill in the art that the present disclosure may be practiced without these specific details. In other instances, well-known methods, procedures, systems, and components have not been described in detail so as not to unnecessarily obscure aspects of the various embodiments.

Hereinafter, an embodiment of the present disclosure will be described with reference to the drawings. Throughout the drawings, the same components are designated by the same reference numerals, and the duplicated descriptions thereof may be omitted.

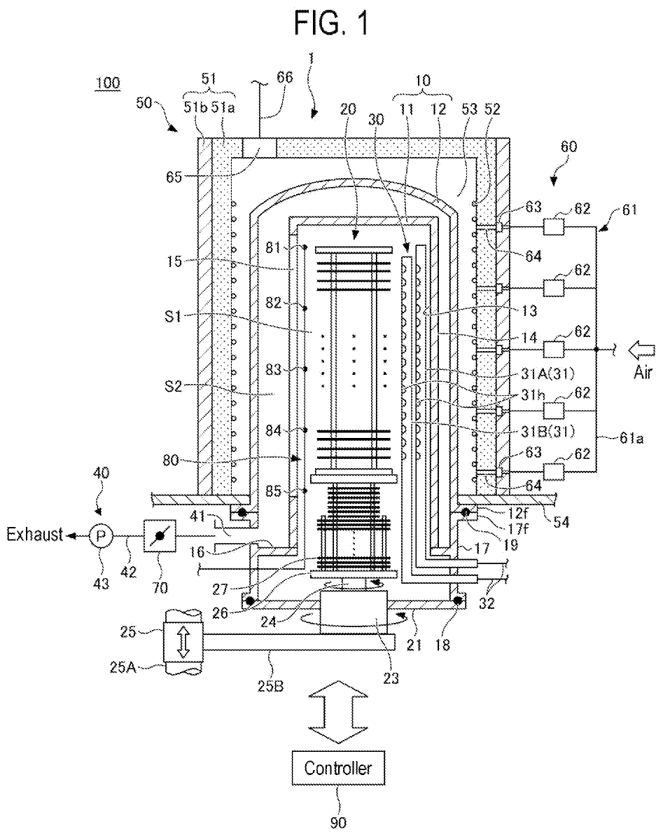

To facilitate understanding of the valve according to the embodiment of the present disclosure, first, an example of a substrate processing apparatus to which the valve is applied will be described with reference to FIG. 1.

A substrate processing apparatus 1 is a vertical heat treatment apparatus that vertically arranges and holds a plurality of substrates W and forms a desired film on a surface of each substrate W by an atomic layer deposition (ALD) method, a chemical vapor deposition (CVD) method, a thermal oxidation method, or other methods. The substrate W on which a film is to be formed is not particularly limited. Examples of the substrate W include a semiconductor substrate such as a silicon wafer or a compound semiconductor wafer, or a glass substrate.

The substrate processing apparatus 1 includes a processing container 10 that accommodates each substrate W and performs film formation, a gas supply 30 that supplies gases into the processing container 10, a gas exhauster 40 that exhausts gases from an interior of the processing container 10, and a temperature adjustment furnace 50 that is disposed around the processing container 10. The substrate processing apparatus 1 further includes a controller 90 that controls individual components of a system including the substrate processing apparatus 1.

The processing container 10 is formed in a cylindrical shape and is installed so that its axis extends along a vertical direction (up-down direction). The processing container 10 has a double-cylinder structure including an inner cylinder 11 and an outer cylinder 12 that accommodates the inner cylinder 11. The inner cylinder 11 and the outer cylinder 12 are made of a heat-resistant material such as quartz or the like and are disposed coaxially with each other. The processing container 10 is not limited to the double-cylinder structure, and may have a single-cylinder structure or a multiple-cylinder structure constituted by three or more cylinders.

The inner cylinder 11 has an open lower end and a ceiling wall at its upper end. The inner cylinder 11 has an inside diameter larger than a diameter of each substrate W. An interior of the inner cylinder 11 serves as a processing space S1 in which gases are supplied to each of the accommodated substrates W to form a film. An opening 15 is provided at an appropriate circumferential position of the inner cylinder 11 to flow gases from the processing space S1 to a flow space S2 between the inner cylinder 11 and the outer cylinder 12. The opening 15 may be formed in the ceiling wall of the inner cylinder 11, for example.

Further, the inner cylinder 11 has an accommodator 13 capable of accommodating gas supply nozzles 31 of the gas supply 30 at a circumferential position opposite the opening 15. As an example, the accommodator 13 is provided in a protrusion 14, which is a portion of a side wall of the inner cylinder 11 protruding radially outward.

The outer cylinder 12 has an inside diameter larger than that of the inner cylinder 11 and covers the inner cylinder 11 without being in contact with the inner cylinder 11. The flow space S2 formed in the outer cylinder 12 is continuous on upper and lateral sides of the inner cylinder 11, and allows the gases moved from the opening 15 to flow vertically downward.

A lower end of the processing container 10 is supported by a cylindrical manifold 17 made of stainless steel. The manifold 17 has a manifold-side flange 17f at its upper end. The manifold-side flange 17f fixes and supports an outer cylinder-side flange 12f formed at a lower end of the outer cylinder 12. A seal 19 that seals the outer cylinder 12 and the manifold 17 airtightly is provided between the outer cylinder-side flange 12f and the manifold-side flange 17f. Further, the manifold 17 has an annular support plate 16 on its upper inner wall. The support plate 16 protrudes radially inward from the inner wall to fix and support a lower end of the inner cylinder 11.

A lid 21 is disposed at a lower end opening of the manifold 17. The lid 21 is configured to be movable in the vertical direction by a lifter 25 to open and close the lower end opening of the manifold 17 (see also FIG. 1). A lower end of the manifold 17 has a seal 18 that closes the lower end opening of the manifold 17 airtightly according to a closing operation of the lid 21. After a wafer boat 20 is accommodated in the processing container 10 and the manifold 17, interiors of the processing container 10 and the manifold 17 are sealed according to the closing operation of the lid 21.

The wafer boat 20 is a substrate holder that holds the plurality of substrates W. A longitudinal direction of the wafer boat 20 extends along the vertical direction, and the wafer boat 20 holds outer edges of the substrates W by a plurality of shelves (not shown). While being held by the wafer boat 20, the substrates W are arranged at regular intervals along the vertical direction, and are supported horizontally with one another.

The substrate processing apparatus 1 further includes a rotator 23 that rotatably supports the wafer boat 20, and the lifter 25 that supports the wafer boat 20 via the rotator 23 and moves the wafer boat 20 vertically.

The rotator 23 includes a rotary source (not shown), a rotary shaft 24 rotated by the rotary source, and a rotary plate 26 connected to an upper end of the rotary shaft 24. The wafer boat 20 is placed on an upper surface of the rotary plate 26 via a heat insulator 27. The rotator 23 rotates the rotary shaft 24 and the rotary plate 26 to rotate the heat insulator 27 and the wafer boat 20 about a vertical axis.

The lifter 25 includes a column 25A extending in the vertical direction, an arm 25B that can move vertically relative to the column 25A, and a lifting drive (not shown) that moves the arm 25B vertically. The arm 25B extends in a horizontal direction and supports members (the wafer boat 20, the rotary plate 26, and the heat insulator 27) disposed above the rotator 23 at its extended end. By moving the arm 25B of the lifter 25 vertically, the substrate processing apparatus 1 vertically moves the lid 21, the rotator 23, and members disposed above the rotary shaft 24 as a whole, thereby loading and unloading the wafer boat 20 with respect to the interior of the processing container 10.

The gas supply 30 includes one or more gas supply nozzles 31 for supplying gases to each substrate W disposed in the processing space S1. The gases supplied by the gas supply 30 include a raw material gas for depositing a precursor on the substrate W, a reaction gas that reacts with the precursor, a purge gas that purges the processing space S1, and the like.

In the embodiment, the gas supply 30 includes two gas supply nozzles 31 (a first gas supply nozzle 31A and a second gas supply nozzle 31B). The first gas supply nozzle 31A is a nozzle that supplies a raw material gas and a purge gas into the processing container 10. The second gas supply nozzle 31B is a nozzle that supplies a reaction gas into the processing container 10. In addition, the gas supply 30 is not limited to the configuration described above, and may include gas supply nozzles 31 for each type of a raw material gas, a reaction gas, and a purge gas (i.e., three or more gas supply nozzles). Conversely, the gas supply 30 may be configured to supply a raw material gas, a reaction gas, and a purge gas by a single gas supply nozzle 31.

Each of the gas supply nozzles 31 (the first gas supply nozzle 31A and the second gas supply nozzle 31B) are quartz-made injector pipes, and are fixed to the manifold 17. Each gas supply nozzles 31 extend in the inner cylinder 11 along the vertical direction, and are bent in an L-shape at a lower end thereof to penetrate the manifold 17. Each gas supply nozzle 31 has a plurality of gas holes 31h arranged at regular intervals along the vertical direction in the inner cylinder 11, and discharges gases from the respective gas holes 31h in the horizontal direction. The intervals of the gas holes 31h are set to be the same as the intervals of the substrates W supported by the wafer boat 20, for example. In addition, position of each gas hole 31h in the vertical direction is set to be located in the middle between adjacent ones of the substrates W in the vertical direction. Thus, each gas hole 31h can smoothly supply gases to a gap between the substrates W.

The gas supply 30 has a plurality of gas supply paths 32 connected to the first gas supply nozzle 31A and the second gas supply nozzle 31B at locations outside the processing container 10. The gas supply path 32 connected to the first gas supply nozzle 31A branches off at an intermediate position and is connected to a raw material gas source and a purge gas source (which are not shown). The gas supply path 32 connected to the second gas supply nozzle 31B is connected to a reaction gas source (not shown). Each gas supply path 32 is provided with a flow rate regulator (not shown) for regulating a flow rate of a gas, a valve for opening and closing a flow path in the gas supply path 32, and the like (all of which are not shown), at intermediate positions on the way to each gas source.

The gas exhauster 40 exhausts gases existing in the processing container 10 to the outside. The gas supplied by each gas supply nozzle 31 moves from the processing space S1 of the inner cylinder 11 to the flow space S2, and is then exhausted via a gas outlet 41. The gas outlet 41 is formed in an upper side wall of the manifold 17 and above the support plate 16. An exhaust path 42 of the gas exhauster 40 is connected to the gas outlet 41.

The gas exhauster 40 further includes a valve 70 and a vacuum pump 43, which are disposed in the named order from an upstream side to a downstream side of the exhaust path 42. The vacuum pump 43 generates a suction pressure by driving a suction drive (not shown) to suck gases from the interior of the processing container 10. The valve 70 is an automatic pressure control (APC) valve that can regulate a pressure in the processing container 10 by opening and closing the exhaust path 42 or changing an open degree thereof. A configuration of the valve 70 will be described in detail later.

A temperature sensor 80 that detects a temperature in the processing container 10 is provided in the processing container 10 (e.g., the processing space S1 in the inner cylinder 11). The temperature sensor 80 includes a plurality of (five in this embodiment) temperature detectors 81 to 85 disposed at different positions in the vertical direction. The temperature detectors 81 to 85 may be thermocouples, temperature measurement resistors, or the like. The temperature sensor 80 transmits temperatures detected by the temperature detectors 81 to 85 to the controller 90.

In addition, the temperature adjustment furnace 50 covers an entirety of processing container 10 and heats and cools each substrate W accommodated in the processing container 10 from the outside. Specifically, the temperature adjustment furnace 50 includes a cylindrical housing 51 having a ceiling, and a heater 52 provided in the housing 51.

The housing 51 is attached to an upper surface of a base plate 54 located at a boundary between the processing container 10 and the manifold 17, and heats the processing container 10 accommodated therein. The housing 51 is spaced apart from the processing container 10 to form a temperature adjustment space 53 between the processing container 10 and the housing 51.

The housing 51 includes a heat insulator 51a having a ceiling and covering the entirety of the processing container 10, and a reinforce 51b for reinforcing the heat insulator 51a on an outer periphery side of the heat insulator 51a. In order to suppress thermal influence on the outside of the temperature adjustment furnace 50, an outer periphery side of the reinforce 51b is covered with a water-cooling jacket (not shown).

Further, the temperature adjustment furnace 50 includes a cooler 60 that circulates a cooling gas such as the air or the like in the temperature adjustment space 53 in order to cool the processing container 10 during or after film formation. The cooler 60 includes an external supply path 61 and flow rate regulators 62, which are provided outside the temperature adjustment furnace 50, supply flow paths 63 provided in the reinforce 51b, and a plurality of supply holes 64 provided in the heat insulator 51a.

Furthermore, the cooler 60 includes an exhaust hole 65 formed in the ceiling of the housing 51 to discharge the air supplied into the temperature adjustment space 53. The exhaust hole 65 is connected to an external exhaust path 66 provided outside the housing 51.

In addition, in the above-described example, as the substrate processing apparatus 1, an apparatus that supplies a raw material gas and a reaction gas as a processing gas to form a desired film on the surface of each substrate W has been described. However, the substrate processing apparatus 1 is not limited to being applied to a film forming apparatus as a heat treatment apparatus. For example, the substrate processing apparatus 1 may be applied to, as a heat treatment apparatus, an apparatus that etches a film on the surface of each substrate W or an apparatus that modifies or cleans the surface of each substrate W. The heat treatment apparatus may also be configured to generate plasma in the processing container 10.

The controller 90 of the substrate processing apparatus 1 may be a computer including a processor, a memory, an input/output interface, a communication interface, and the like. The processor may be one or a combination of a central processing unit (CPU), a graphics processing unit (GPU), an application specific integrated circuit (ASIC), a field-programmable gate array (FPGA), a circuit made of a plurality of discrete semiconductors, and the like. The memory may include a main storage device formed by a semiconductor memory or the like, and an auxiliary storage device formed by a disk, a semiconductor memory (flash memory), and the like. The memory may be configured by appropriately combining a volatile memory and a non-volatile memory (e.g., a compact disk, a digital versatile disk (DVD), a hard disk, a flash memory, and the like).

The memory stores a program for operating the substrate processing apparatus 1 and a recipe such as conditions of a heat treatment process and the like. The processor reads and executes the program stored in the memory to control individual components of the substrate processing apparatus 1. In other words, the controller 90 of the present disclosure is an electronic circuit having a CPU, a GPU, an ASIC, an FPGA, and the like, and performs various control operations described in the present specification by executing instruction codes stored in the memory or by being circuit-designed for a special purpose. In addition, the controller may be configured by a host computer and a plurality of client computers that perform information communication via a network. The substrate processing apparatus 1 is not limited to a configuration in which the controller 90 directly controls individual apparatuses, but may also have a configuration in which dedicated control devices are provided for appropriate apparatuses (e.g., the substrate processing apparatus 1) and control commands of the controller 90 are sent to the control devices to control individual apparatuses by the control devices.

In the substrate processing apparatus 1 described above, when substituting a gas in the processing container 10, it is desired to improve efficiency of processing by purging the gas in the processing container 10 under a low pressure and at a large flow rate by the gas exhauster 40. In particular, the valve 70 for pressure control in the gas exhauster 40 serves as a rate-limiting point for an exhaust speed of the processing gas and by configuring the valve 70 to exhaust a gas at a large flow rate, it is possible to reduce a load on the vacuum pump 43.

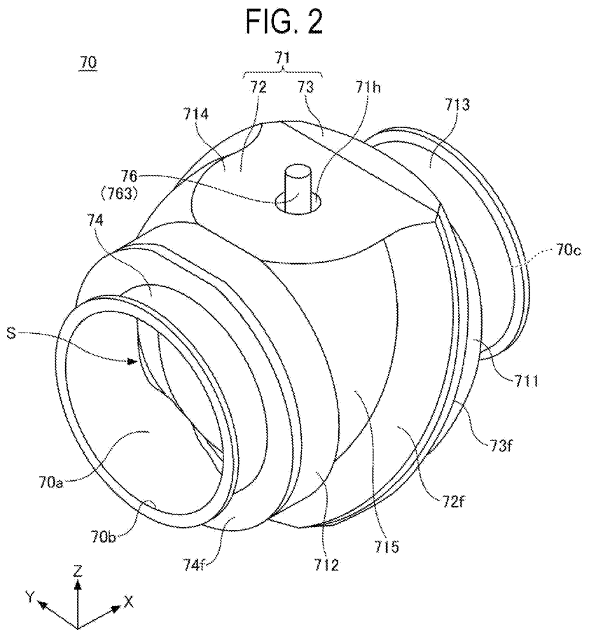

Next, a configuration of the valve 70 that implements a gas exhaust at a large flow rate will be described in detail with reference to FIG. 2. For ease of explanation, positions of individual components of the valve 70 will be illustrated based on arrows in an X-axis direction, a Y-axis direction, and a Z-axis direction shown in FIG. 2.

The valve 70 extends linearly along the X-axis direction, and allows a fluid such as a gas or the like to flow linearly from one end to the other end. Both ends of the valve 70 in the X-axis direction are connected to pipes that constitute the exhaust path 42 (see FIG. 1). The valve 70 has an internal flow path 70a which is in communication with pipelines of the respective pipes, and through which a fluid can flow. The valve 70 also has an inlet 70b at one end (an end in the X-axis negative direction) of the flow path 70a, and an outlet 70c at the other end (an end in the X-axis positive direction) of the flow path 70a.

Specifically, the valve 70 includes a housing 71 and a valve body 76 provided in the housing 71 to open and close the flow path 70a.

The housing 71 includes a substantially spherical main body 711 located in the middle in the X-axis direction, an inflow cylinder 712 connected to the main body 711 in the X-axis negative direction, and an outflow cylinder 713 connected to the main body 711 in the X-axis positive direction. The housing 71 also includes a sealing tube 74 fixed to the inflow cylinder 712.

The main body 711 of the housing 71 axially supports the valve body 76 so that the valve body 76 can rotate, and constitutes a portion that switches between opening and closing the internal flow path 70a according to a rotation of the valve body 76. When the valve body 76 is in an open state, the main body 711 receives a fluid from the inflow cylinder 712 (sealing tube 74) and allows the fluid to flow out to the outflow cylinder 713.

Further, the main body 711 has flat portions 714 at both ends in the Z-axis direction. A through-hole 71h that rotatably accommodates a rotary shaft 763 of the valve body 76 is formed in each flat portion 714. By the flat portions 714, a thickness of the valve 70 in the Z-axis direction can be made smaller than a width thereof in the Y-axis direction. For example, a drive mechanism (not shown) that rotates the valve body 76 is attached to the flat portions 714. A seal, which closes a gap generated when the rotary shaft 763 is accommodated in the through-hole 71h while allowing the rotary shaft 763 to rotate, is provided in each through-hole 71h.

Furthermore, the housing 71 has a spherical portion 715 at a circumferentially adjacent position in the Y-axis direction from the flat portions 714. The spherical portion 715 bulges an internal space of the main body 711 radially outward, thereby forming a standby portion where the valve body 76 that opens the flow path 70a is located.

The housing 71 according to the embodiment can be divided into two members (a first housing 72 and a second housing 73) in the X-axis direction, in order to improve machinability of the housing 71 and to enable assembly of the valve body 76. In FIG. 2, the first housing 72 is located on an X-axis negative side, and the second housing 73 is located on an X-axis positive side. A boundary between the first housing 72 and the second housing 73 is inclined with respect to the X-axis direction and the Z-axis direction in the main body 711.

The first housing 72 includes a portion of the main body 711 on the X-axis negative side and the inflow cylinder 712. The first housing 72 has almost all of the flat portion 714 on a Z-axis positive side, and the through-hole 71h on the Z-axis positive side. Further, an end surface of the first housing 72 on the X-axis positive side, which constitutes the boundary, is formed into an elliptical shape in conformity with the inclination. Furthermore, the first housing 72 has an arc-shaped flange 72f, which constitutes the boundary, on an outer circumferential surface of the main body 711 in the Y-axis direction.

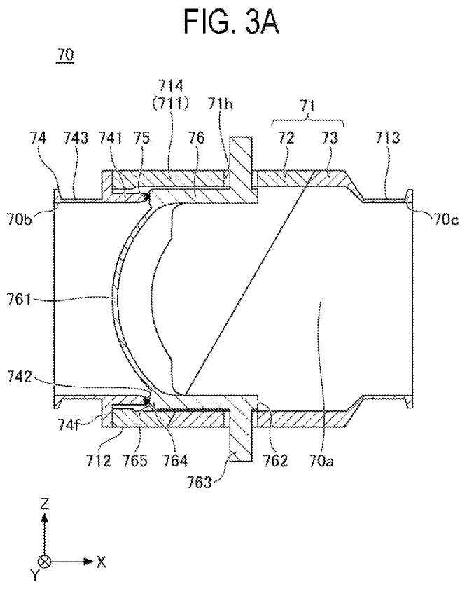

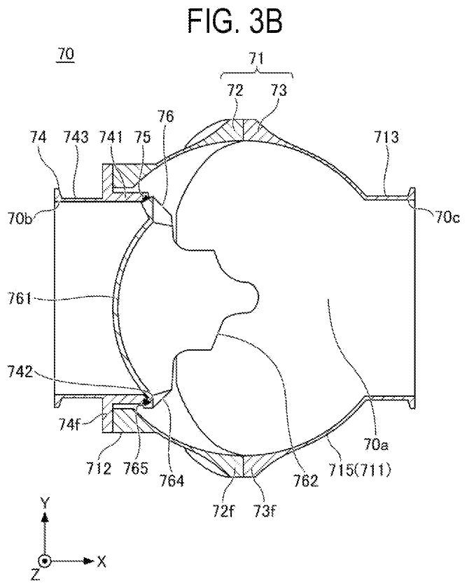

The second housing 73 includes a portion of the main body 711 on the X-axis positive side and the outflow cylinder 713. The second housing 73 has almost all of the flat portion 714 on a Z-axis negative side, and the through-hole 71h on the Z-axis negative side (see also FIG. 3A). Further, an end surface of the second housing 73 on the X-axis negative side, which constitutes the boundary, is formed into an elliptical shape (the same shape as the end surface of the first housing 72) in conformity with the inclination. Furthermore, the second housing 73 also has an arc-shaped flange 73f, which constitutes the boundary, on the outer circumferential surface of the main body 711 in the Y-axis direction.

When assembling the valve 70, the valve body 76 is inserted into each through-hole 71h before fixing the first housing 72 (including the sealing tube 74) and the second housing 73. Thereafter, the end surface at the boundary of the first housing 72 and a facing surface of the flange 72f and the end surface at the boundary portion of the second housing 73 and a facing surface of the flange 73f are overlapped with each other and fixed by a fixing means such as welding, adhesion, or screwing. By the sequence described above, the valve 70 can be easily constructed in a state in which the valve body 76 is accommodated in the housing 71.

In addition, the housing 71 may include a seal (not shown) such as an O-ring at the boundary between the first housing 72 and the second housing 73. With this configuration, airtightness of the main body 711 in the housing 71 can be increased. In addition, division of the first housing 72 and the second housing 73 of the housing 71 is not limited to that described above, and the first housing 72 and the second housing 73 may be divided, for example, in an axial direction along the X-axis direction.

The sealing tube 74 is fixed to the inflow cylinder 712, and constitutes an inflow port for a fluid at one end in the X-axis negative direction and a seal portion S in cooperation with the valve body 76 at the other end in the X-axis positive direction. The sealing tube 74 has a circular tubular shape that extends a short distance in the X-axis direction.

As shown in FIGS. 3A and 3B, the sealing tube 74 has a tube-side flange 74f that protrudes radially outward from an outer circumferential surface thereof and goes around in an annular shape. The tube-side flange 74f is connected to an end surface of the inflow cylinder 712 of the housing 71 by a fixing means such as welding, adhesion, or screwing. In addition, the valve 70 may include a seal (not shown) such as an O-ring at a boundary between the end surface of the inflow cylinder 712 and the tube-side flange 74f of the sealing tube 74. With this configuration, airtightness of a connection portion between the housing 71 and the sealing tube 74 in the valve 70 can be increased.

In addition, the sealing tube 74 includes an inner peripheral wall 741 which protrudes in the X-axis positive direction beyond the tube-side flange 74f and extends in the inflow cylinder 712, and an outer peripheral wall 743 which protrudes in the X-axis negative direction beyond the tube-side flange 74f and constitutes the inlet 70b. The outer peripheral wall 743 is formed to have approximately the same inside and outside diameters as those of the outflow cylinder 713 of the housing 71, and is connected to the pipe of the exhaust path 42.

The inner peripheral wall 741 is formed to be thicker than the outer peripheral wall 743 in order to form the seal portion S between the inner peripheral wall 741 and the valve body 76. An end surface of the inner peripheral wall 741 in the X-axis positive direction is located in the main body 711 of the housing 71, and serves as a housing seal surface 742 that holds a seal 75. The housing seal surface 742 is formed in an annular shape that goes around along a circumferential direction of the inner peripheral wall 741 and surrounds the flow path 70a. In addition, the housing seal surface 742 is formed so that an orientation thereof is changed along the circumferential direction in conformity with a valve body seal surface 765 of the valve body 76 described later, and is formed in a wavy shape (so as to have unevenness) along the X-axis direction. The shape of the housing seal surface 742 will be described in detail later.

The seal 75 is an O-ring or the like that extends annularly along the housing seal surface 742 of the sealing tube 74. The seal 75 is accommodated in and fixed to a recessed groove provided on the housing seal surface 742 so as to protrude slightly from the housing seal surface 742. Examples of a material for the seal 75 include well-known resin materials that can ensure airtightness, such as rubber (elastic material) and the like.

As described above, the valve body 76 is rotatably accommodated in the main body 711 of the housing 71. The valve body 76 has a main blocker 761, a pair of support walls 762 supporting both ends of the main blocker 761 in the Z-axis direction, and a pair of rotary shafts 763 protruding outward from the pair of support walls 762.

The main blocker 761 is formed in a substantially hemispherical shape (arc shape in a cross section) having a smaller radius than the main body 711, and is disposed at a position facing a center portion of the flow path 70a when the valve body 76 is in a closing state. The main blocker 761 has a convex shape (bowl shape) with a center portion thereof protruding toward the inlet 70b relative to an outer peripheral portion thereof when the valve body 76 is in the closing state. The shape of the main blocker 761 is not particularly limited, and the main blocker 761 may be formed flat, for example.

The pair of support walls 762 protrude in a direction opposite to the convex shape of the main blocker 761 (in the X-axis positive direction when the valve body 76 is in the closing state). The pair of support walls 762 are formed in a flat plate shape, and extend parallel to the flat portion 714 of the housing 71 with the rotary shaft 763 axially supported by the housing 71. Each support wall 762 narrows in a step shape toward the X-axis positive direction in a plan view, and supports the rotary shaft 763 at its end in the X-axis positive direction.

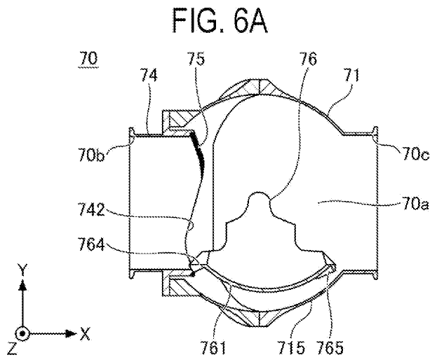

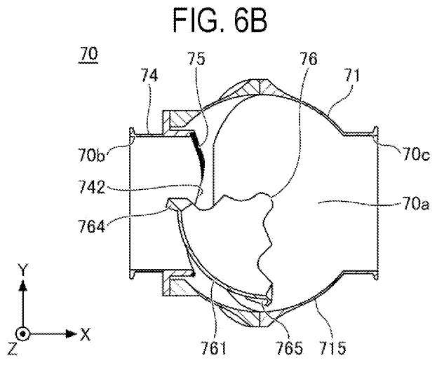

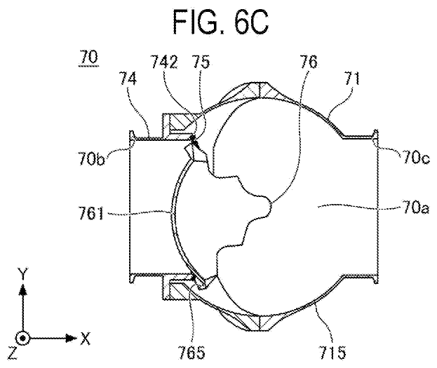

The pair of rotary shafts 763 are formed in a cylindrical shape and protrude outward (in the Z-axis positive direction and the Z-axis negative direction) from an outer surface of each support wall 762. One of the rotary shafts 763 is inserted into the through-hole 71h of the housing 71 in the Z-axis positive direction. The other of the rotary shafts 763 is inserted into the through-hole 71h of the housing 71 in the Z-axis negative direction. Thus, the valve body 76 is axially supported to be rotatable about the Z axis relative to the housing 71. The main blocker 761 supported by each rotary shaft 763 via each support wall 762 moves between a fully closing position, which is a position where the main blocker 761 faces the sealing tube 74 and closes the flow path 70a, and a fully open position (see also FIG. 6A), which is a position where the main blocker 761 is rotated approximately 90 degrees from the fully closing position and opens the flow path 70a. At the fully open position, the main blocker 761 is disposed in the spherical portion 715 of the housing 71, so that the linear flow path 70a of the valve 70 is widely opened.

One or both of the pair of rotary shafts 763 are connected to a drive mechanism, which rotates the valve body 76, at a portion thereof protruding outward from the through-hole 71h of the housing 71. By controlling a rotational position of the valve body 76 based on operations of the drive mechanism, it is possible to open and close the flow path 70a and to adjust an open degree of the valve body 76 with respect to the flow path 70a.

Further, the valve body 76 according to the embodiment has an annular outer periphery portion 764 that is continuous with an outer edge of the hemispherical main blocker 761. A valve body seal surface 765 that can be brought into contact with the seal 75 of the sealing tube 74 is formed in the outer periphery portion 764. In a closing operation of the valve body 76, the valve body seal surface 765 is brought into contact with the housing seal surface 742 and crushes the seal 75, so that the flow path 70a is closed airtightly.

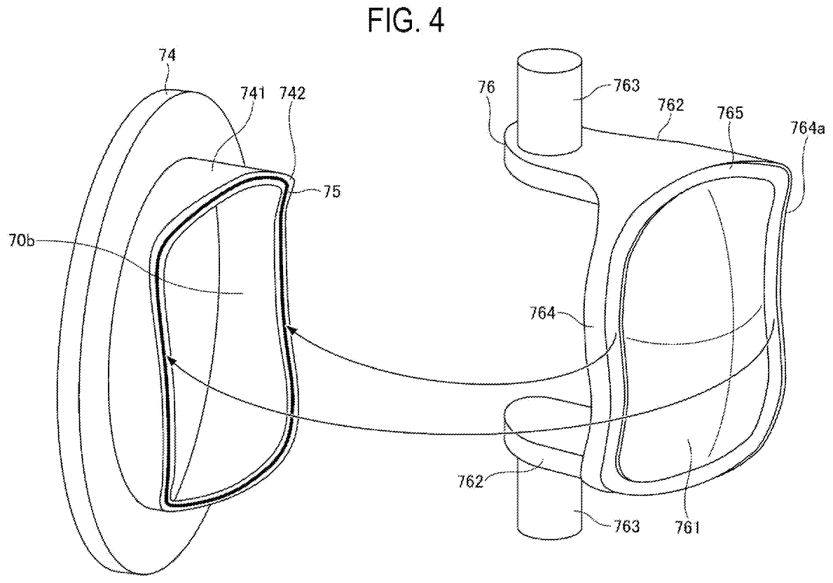

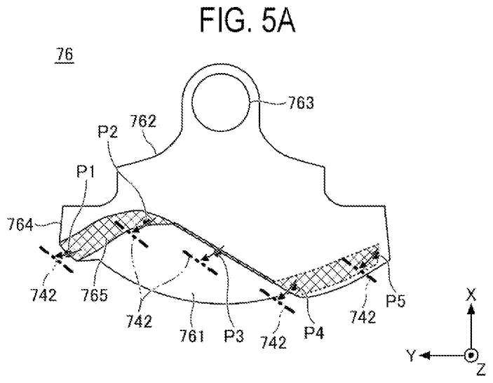

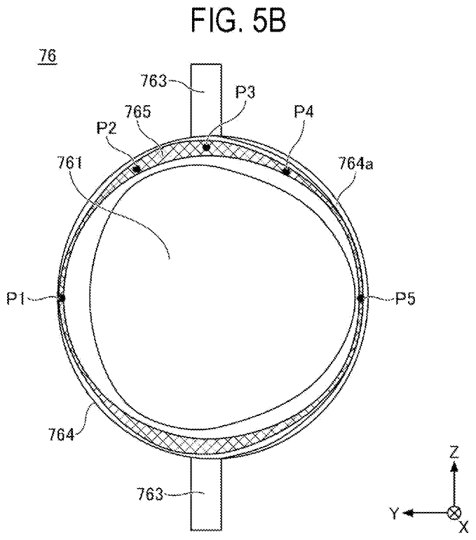

Furthermore, the valve body 76 according to the embodiment has a shape that can reduce, in the closing operation of the valve body 76 accompanying the rotation thereof, an amount of sliding of the valve body seal surface 765 against the housing seal surface 742 (in other words, the seal 75) as much as possible. Hereinafter, the seal portion S formed by the valve body seal surface 765 of the valve body 76 and the housing seal surface 742 of the sealing tube 74 will be described with reference to FIG. 4 and FIGS. 5A and 5B.

The valve body seal surface 765 of the valve body 76 according to the embodiment faces a rotation direction (a closing rotation direction) of the valve body 76 closing the flow path 70a over an entire circumference of the outer periphery portion 764. The closing rotation direction of the valve body 76 closing the flow path 70a is a clockwise direction when viewed from a Z-axis positive direction side as shown in FIG. 3B. Therefore, the valve body seal surface 765 faces the clockwise direction at a position spaced apart from the rotary shaft 763, which is a rotation center, by a predetermined radius. The closing rotation direction may be set according to an installation position of the valve body 76, and may be a counterclockwise direction when the fully open position is on the Y-axis positive direction side, for example.

In order to implement the shape described above, the valve body seal surface 765 adopts a shape that is gradually twisted 180 degrees in the circumferential direction of the outer periphery portion 764, as shown in FIGS. 5A and 5B. In other words, the valve body seal surface 765 forms a Möbius strip. This shape will be described below using an upper portion (a portion on an upper side in the Z-axis direction) of the valve body seal surface 765 as an example.

In the valve body seal surface 765, a leading end position in the closing rotation direction of the valve body 76 is defined as P1, a position shifted 60 degrees from the position P1 in the circumferential direction of the valve body seal surface 765 is defined as P2, and a position shifted 30 degrees from the position P2 in the circumferential direction of the valve body seal surface 765 is defined as P3. Further, in the valve body seal surface 765, a position shifted 30 degrees from the position P3 in the circumferential direction of the valve body seal surface 765 is defined as P4, and a position shifted 60 degrees from the position P4 in the circumferential direction of the valve body seal surface 765 is defined as P5. In this case, the position P5 is located at a trailing end in the closing rotation direction of the valve body 76. Furthermore, the position P3 overlaps with the rotary shaft 763 of the valve body 76, and exists at an intermediate position between the leading end position P1 and the trailing end position P5 in the circumferential direction of the outer periphery portion 764.

The valve body seal surface 765 at the position P1 is inclined radially outward and toward the rotary shaft 763. The valve body seal surface 765 at the position P2 is closer to the rotary shaft 763 than at the position P1, and is inclined radially outward and toward the rotary shaft 763 by a gentler angle than at the position P1. Over a vicinity of the position P2 (within a range of about 20 degrees in the circumferential direction), the valve body seal surface 765 is formed to be gradually twisted with respect to the position P1. Around the position P2, the valve body seal surface 765 is twisted by approximately 90 degrees. At the position P3, the valve body seal surface 765 is distanced farther from the rotary shaft 763 than at the position P2, faces the X-axis negative direction, and is inclined with respect to the Y-axis direction.

At the position P4, the valve body seal surface 765 is distanced farther from the rotary shaft 763 than at the position P3, and is inclined radially outward and in a direction away from the rotary shaft 763 by a gentle angle. From the position P4 to the position P5, the valve body 76 has a return portion 764a which is the outer periphery portion 764 protruding in the X-axis negative direction with respect to the outer periphery portion 764 at the position P1. The valve body seal surface 765 is formed in the return portion 764a. Over a vicinity of the position P4 (within a range of about 20 degrees in the circumferential direction), the valve body seal surface 765 is formed to be gradually twisted with respect to the position P3. Around the position P4, the valve body seal surface 765 is twisted by approximately 90 degrees. At the position P5, the valve body seal surface 765 is located closer to the rotary shaft 763 than at the position P4, and is inclined radially inward and in a direction away from the rotary shaft 763 by a gentle angle. In other words, the valve body seal surface 765 has unevenness in the X-axis direction (a front-rear direction orthogonal to the circumferential direction of the outer periphery portion 764) from the position P1 to the position P5.

The valve body seal surface 765 described above has twisted portions, in which the inclination of the valve body seal surface 765 changes gradually, in the vicinities of the positions P2 and P4. Thus, the valve body seal surface 765 has a shape, which extends continuously along the circumferential direction of the outer periphery portion 764 and faces the closing rotation direction of the valve body 76 at all positions including the positions P1 to P5. In addition, correspondingly to the valve body seal surface 765 having the twisted portions, the housing seal surface 742 is also formed to have similar twisted portions (see also FIG. 4). With this configuration, the housing seal surface 742 and the valve body seal surface 765 face each other as the valve body 76 rotates in the closing rotation direction, and the valve body seal surface 765 can be smoothly brought into contact with the seal 75 in the housing seal surface 742.

In particular, in the valve body seal surface 765 according to the embodiment, a surface orientation is adjusted so that a contact angle between the valve body seal surface 765 and the housing seal surface 742 of the sealing tube 74 is 30 degrees or more over the entire circumference of the outer periphery portion 764. The contact angle refers to an angle when the valve body seal surface 765 in rotation is brought into contact with the seal 75, given that a tangent of the closing rotation direction is 0 degrees and a normal of the closing rotation direction is 90 degrees. When the contact angle is 0 degrees, an amount of sliding (rubbing) of the valve body seal surface 765 against the seal 75 is maximized. Therefore, the contact angle may be set to an angle greater than 0 degrees, for example, 1 degrees or more. More specifically, when the contact angle is 30 degrees or more, it is possible to significantly reduce a sliding amount, which is the amount of sliding (rubbing) of the valve body seal surface 765 against the seal 75 held by the housing seal surface 742.

Specifically, since the valve body seal surface 765 has unevenness in the X-axis direction from the position P1 to the position P5 as shown in FIG. 5A, the contact angle at each position can be set to 30 degrees or more. For example, at the position P1, the inclined valve body seal surface 765 is brought into contact with the housing seal surface 742 with a contact angle of at 30 degrees or more. At the position P2, since the valve body seal surface 765 is convex toward the rotary shaft 763 than at the position P1, the valve body seal surface 765 is brought into contact with the housing seal surface 742 at a contact angle closer to 90 degrees than at the position P1. At the position P3, since the valve body seal surface 765 protrudes in a direction away from the rotary shaft 763 with respect to the position P2, the valve body seal surface 765 is brought into contact with the housing seal surface 742 at a contact angle closer to 90 degrees than at the position P2. At the position P4, since the valve body seal surface 765 protrudes in a direction away from the rotary shaft 763 with respect to the position P3, the valve body seal surface 765 is brought into contact with the housing seal surface 742 at a contact angle similar to that at the position P2. The position P5 is recessed from the position P4 with respect to the rotary shaft 763. However, since the position P5 is formed in the return portion 764a, the contact angle is adjusted to an angle (a contact angle close to 90 degrees) that allows the return portion 764a to face the housing seal surface 742.

Therefore, the housing seal surface 742 and the valve body seal surface 765 face each other while reducing the amount of sliding in the circumferential direction during the rotation in the closing rotation direction. In other words, in the valve 70, since friction between the seal 75 and the valve body seal surface 765 in the closing operation is reduced, it is possible to increase durability of the seal 75.

The valve 70 according to the embodiment and the substrate processing apparatus 1 including the valve 70 are basically configured as described above, and below, operations thereof will be described with reference to FIGS. 6A to 6C.

When the valve 70 fully opens the flow path 70a, the valve body 76 stands by at the fully open position as shown in FIG. 6A based on a drive of the drive mechanism. The main blocker 761 of the valve body 76 is disposed in the spherical portion 715 of the housing 71, so that the flow path 70a can be widely opened. Thus, pressure loss of the fluid flowing through the flow path 70a due to contact with the valve body 76 is reduced, and the fluid can flow through the housing 71 at a large flow rate.

In addition, when adjusting the pressure in the processing container 10 of the substrate processing apparatus 1, the valve body 76 is positioned, for example, as shown in FIG. 6B by rotating the valve body 76 from the fully open position by an appropriate rotation angle to reduce the open degree of the flow path 70a. The valve 70 can appropriately limit the flow rate of the fluid by closing a part of the flow path 70a while opening the other part of the flow path 70a.

When the valve 70 fully closes the flow path 70a, based on a drive of the drive mechanism, the valve body 76 is rotated in the closing rotation direction to move to the fully closing position as shown in FIG. 6C. FIG. 6C is a cross-sectional plan view showing a state before the valve body 76 fully closes the flow path 70a. The state in which the valve body 76 fully closes the flow path 70a is shown in FIG. 3B. As described above, as the valve body 76 rotates in the closing rotation direction, the valve body seal surface 765 approaches the housing seal surface 742. At a position close to the housing seal surface 742, the valve body seal surface 765 has a contact angle of 30 degrees or more, so that the amount of sliding of the valve body seal surface 765 against the housing seal surface 742 can be significantly reduced.

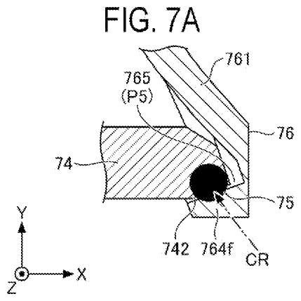

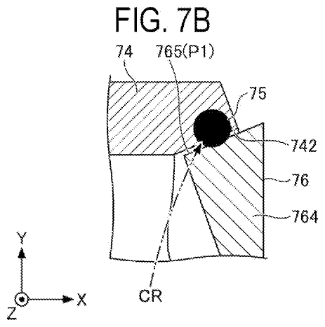

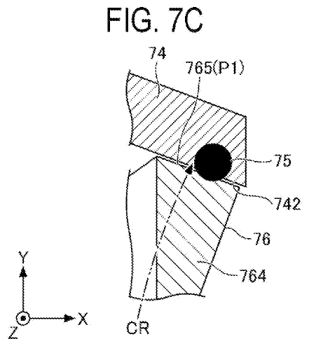

When the valve body 76 has moved to the fully closing position, as shown in FIG. 7A, the position P5 of the valve body seal surface 765 formed in the return portion 764a faces the housing seal surface 742 which is an inclined surface on an outer side of the sealing tube 74. In detail, the valve body seal surface 765 is moved with the rotation of the valve body 76 in the closing rotation direction CR so that the contact angle of the valve body seal surface 765 becomes approximately 90 degrees, and is brought into contact with the housing seal surface 742 while suppressing the sliding against the seal 75. Thus, the valve body seal surface 765 can press the seal 75 with an appropriate force.

In addition, as shown in FIG. 7B, the position P1 of the valve body seal surface 765 faces the housing seal surface 742, which is an inclined surface on an inner side of the sealing tube 74. In detail, the valve body seal surface 765 is moved with the rotation of the valve body 76 in the closing rotation direction CR so that the contact angle of the valve body seal surface 765 becomes 30 degrees or more. Thus, even at the position P1, the valve body seal surface 765 is brought into contact with the housing seal surface 742 while suppressing the sliding, and can press the seal 75 with an appropriate force.

Alternatively, as in another embodiment shown in FIG. 7C, orientations (the contact angle) of the valve body seal surface 765 and the housing seal surface 742 may be adjusted so that they extend along a direction substantially orthogonal to the closing rotation direction CR at the position P1. For example, the valve body seal surface 765 is formed as an inclined surface that substantially coincides with a direction normal to the closing rotation direction CR. The housing seal surface 742 is formed on an inner peripheral surface of the inner peripheral wall 741 of the sealing tube 74 so as to be parallel to the valve body seal surface 765, and holds the seal 75. As described above, by providing the valve body seal surface 765 and the housing seal surface 742 that extend in the direction substantially orthogonal to the closing rotation direction CR, it is possible to further reduce the sliding amount of the valve body seal surface 765.

The valve 70 and the substrate processing apparatus 1 according to the present disclosure are not limited to the embodiment described above, and may take various modifications. For example, the fluid flowing through the valve 70 is not limited to a gas, and may be a liquid or the like.

Further, for example, although the valve 70 according to the embodiment is configured to hold the seal 75 at the housing seal surface 742, the seal 75 may be held at the valve body seal surface 765. Furthermore, the housing 71 may be configured not to include the sealing tube 74, and the housing seal surface 742 sealed with the valve body seal surface 765 of the valve body 76 may be formed directly on an inner surface of the main body 711 or the like.

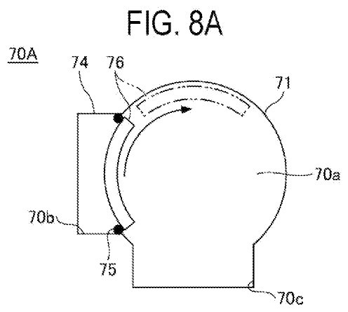

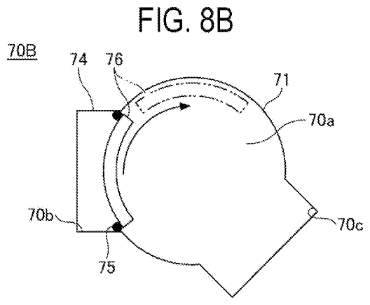

A valve 70A according to a first modification shown in FIG. 8A is different from the valve 70 according to the embodiment in that the inlet 70b and the outlet 70c are provided in directions orthogonal to each other. That is, the flow path 70a of the valve 70A is bent in an orthogonal direction with the main body 711 as a base point. Even in this case, the valve body 76 can perform sealing with a reduced amount of sliding between the housing seal surface 742 and the seal 75 and the valve body seal surface 765, and can stably block a flow of the fluid. In addition, in the valve 70A, a flow of the fluid can be bent in an orthogonal direction by moving the valve body 76 to a fully open position on a side without the outlet 70c.

A valve 70B according to a second modification shown in FIG. 8B is different from the valves 70 and 70A in that the outlet 70c is provided at an inclined position with respect to the inlet 70b. In other words, the valves 70, 70A, and 70B are not particularly limited in a flow direction of the fluid, and can allow the fluid to smoothly flow in a direction based on a shape of the valve.

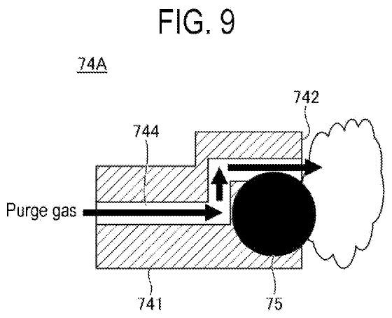

In addition, a sealing tube 74A according to a third modification shown in FIG. 9 is different from those of the valves 70, 70A and 70B in that the sealing tube 74A is configured to discharge a purge gas to the housing seal surface 742 via an interior of the inner peripheral wall 741. Specifically, the inner peripheral wall 741 has a purge gas discharge flow path 744 therein, which bypasses a periphery of the seal 75 and is in communication with an opening of the housing seal surface 742. A base end of the discharge flow path 744 is connected to a purge gas supply (not shown). The discharge flow path 744 discharges the purge gas from the opening of the housing seal surface 742 to a vicinity of the seal 75. Thus, the sealing tube 74 can suppress deterioration of the seal 75, which may be caused when the seal 75 is exposed to a gas in the processing container 10.

Technical ideas and effects of the present disclosure explained in the above-described embodiments will be described below.

A first aspect of the present disclosure is a valve 70, 70A, or 70B including a housing 71 having a flow path 70a of a fluid therein, and a valve body 76 provided rotatably with respect to the housing 71 and configured to open and close the flow path 70a. The housing 71 has a housing seal surface 742 that surrounds the flow path 70a. The valve body 76 has a valve body seal surface 765, which is formed on an outer periphery portion 764 thereof and faces the housing seal surface 742 when the valve body 76 is located at a closing position for closing the flow path 70a. The valve body seal surface 765 faces a closing rotation direction of the valve body 76 for closing the flow path 70a, over an entire circumference of the outer periphery portion 764.

According to the configuration described above, the valve 70, 70A or 70B can open the flow path 70a widely by locating the valve body 76 provided rotatably in the housing 71 at a fully open position for stand-by. Therefore, the valve 70, 70A, or 70B can allow a fluid to flow at a large flow rate. Further, the valve 70, 70A, or 70B has the valve body seal surface 765 facing the closing rotation direction. Thus, it is possible to increase a contact angle of the valve body seal surface 765 with respect to the housing seal surface 742 during rotation in the closing rotation direction to reduce the amount of sliding of the seal portion S. Accordingly, it is possible to suppress damage to the seal portion S in the valve 70, 70A, or 70B, thereby increasing durability of the seal portion S.

In addition, the valve body seal surface 765 may extend continuously while being twisted in a circumferential direction of the outer periphery portion 764. Thus, the valve 70, 70A, or 70B can perform sealing more reliably by the valve body seal surface 765 extending continuously.

In addition, the valve body seal surface 765 may have a leading end position P1 in the closing rotation direction, a trailing end position P5 in the closing rotation direction, and an intermediate position P3 overlapping with a rotary shaft 763 of the valve body 76 and located in a middle of the leading end position P1 and the trailing end position P5, and may include twisted portions between the leading end position P1 and the intermediate position P3, and between the intermediate position P3 and the trailing end position P5. Thus, in the valve 70, 70A, or 70B, the valve body seal surface 765 and the housing seal surface 742 can reliably face each other even at the twisted portions. In addition, the valve body seal surface 765 can reliably face a direction facing the closing rotation direction at the positions P1, P3, and P5.

In addition, the valve body seal surface 765 may have unevenness in a front-rear direction orthogonal to the circumferential direction of the outer periphery portion 764. Thus, it is possible to reliably form a state in which the contact angle between the valve body seal surface 765 and the housing seal surface 742 is 30 degrees or more.

In addition, the outer periphery portion 764 may have a return portion 764a configured to cause the valve body seal surface 765 to face the closing rotation direction at the trailing end position P5 of the valve body seal surface 765 in the closing rotation direction. By providing the return portion 764a as described above, it is possible to easily form a state in which the valve body seal surface 765 of the valve 70, 70A, or 70B faces the closing rotation direction.

In addition, the housing seal surface 742 may hold a seal 75 extending along a circumferential direction of the housing seal surface 742. Thus, since the valve 70, 70A, or 70B has the seal 75 in the housing seal surface 742, which is not rotating, it is possible to avoid influence of the rotation of the valve body 76 on the seal 75.

In addition, the housing 71 may include a sealing tube 74 having the flow path 70a therein, and the housing seal surface 742 may be formed on an end surface of the sealing tube 74. Thus, in the valve 70, 70A, or 70B, even when the housing seal surface 742 is machined complicatedly to match the valve body seal surface 765, the housing seal surface 742 can be easily formed by machining the sealing tube 74.

In addition, the housing 71 may include a flat portion 714 in a vicinity of a portion that axially supports the valve body 76. Thus, the housing 71 of the valve 70, 70A, or 70B can be made smaller in size, and the valve 70, 70A, or 70B can be easily installed in the substrate processing apparatus 1.

In addition, the valve body 76 may include a hemispherical main blocker 761 on an inner side of the outer periphery portion 764, and the housing 71 may include a spherical portion 715, in which the main blocker 761 of the valve body 76 that has opened the flow path 70a stands by, at a position adjacent to the flat portion 714 in a circumferential direction of the housing 71. Thus, in the valve 70, 70A, or 70B, it is possible to further increase a cross-sectional area of the flow path 70a when the valve body 76 opens the flow path 70a.

A second aspect of the present disclosure is a substrate processing apparatus 1 including a processing container 10 configured to accommodate and process a substrate W, an exhaust path 42 connected to the processing container 10 and configured to discharge a gas from the processing container 10, and a valve 70 provided in the exhaust path 42 and configured to control a flow of the gas in the exhaust path 42. The valve 70 includes a housing 71 having a flow path 70a of a fluid therein, and a valve body 76 provided rotatably with respect to the housing 71 and configured to open and close the flow path 70a. The housing 71 has a housing seal surface 742 that surrounds the flow path 70a. The valve body 76 has a valve body seal surface 765, which is formed on an outer periphery portion 764 of the valve body 76 and faces the housing seal surface 742 when the valve body 76 is located at a closing position for closing the flow path 70a. The valve body seal surface 765 faces a closing rotation direction of the valve body 76 for closing the flow path 70a, over an entire circumference of the outer periphery portion 764. Even in this case, the substrate processing apparatus 1 can reduce the sliding amount of the seal portion S while allowing a fluid to flow at a large flow rate.

The valve 70, 70A, or 70B and the substrate processing apparatus 1 according to the embodiments disclosed herein are exemplary and not limitative in all respects. The embodiments may be modified and improved in various ways without departing from the spirit and scope of the appended claims. The matters described in the above embodiments may be configured in other ways without any contradiction, and may be combined without any contradiction.

The substrate processing apparatus 1 to which the valve 70 of the present disclosure is applied is not limited to a vertical heat treatment apparatus, and may be any other batch type apparatus that performs substrate processing on a plurality of substrates W, or a single-substrate type apparatus that performs substrate processing on a single substrate W. In addition, the substrate processing apparatus 1 may be any type of apparatus, such as an atomic layer deposition (ALD) apparatus, a capacitively coupled plasma (CCP) apparatus, an inductively coupled plasma (ICP) apparatus, a radial line slot antenna (RLSA) apparatus, an electron cyclotron resonance plasma (ECR) apparatus, or a helicon wave plasma (HWP) apparatus.

According to the present disclosure in some embodiments, it is possible to reduce an amount of sliding of a valve body while allowing a fluid to flow at a large flow rate.

While certain embodiments have been described, these embodiments have been presented by way of example only, and are not intended to limit the scope of the disclosures. Indeed, the embodiments described herein may be embodied in a variety of other forms. Furthermore, various omissions, substitutions, and changes in the form of the embodiments described herein may be made without departing from the spirit of the disclosures. The accompanying claims and their equivalents are intended to cover such forms or modifications as would fall within the scope and spirit of the disclosures.

What is claimed is:

1. A valve comprising:
a housing having a flow path of fluid in the housing; and
a valve body provided rotatably with respect to the housing, and configured to open and close the flow path,
wherein the housing has a housing seal surface that surrounds the flow path,
wherein the valve body has a valve body seal surface, which is formed on an outer periphery portion of the valve body and faces the housing seal surface when the valve body is located at a closing position for closing the flow path, and
wherein the valve body seal surface faces a closing rotation direction of the valve body for closing the flow path, over an entire circumference of the outer periphery portion.

2. The valve of claim 1, wherein the valve body seal surface extends continuously while being twisted in a circumferential direction of the outer periphery portion.

3. The valve of claim 2, wherein the valve body seal surface has a leading end position in the closing rotation direction, a trailing end position in the closing rotation direction, and an intermediate position overlapping with a rotary shaft of the valve body and located in a middle of the leading end position and the trailing end position, and
wherein the valve body seal surface includes twisted portions between the leading end position and the intermediate position and between the intermediate position and the trailing end position.

4. The valve of claim 3, wherein the valve body seal surface has unevenness in a front-rear direction orthogonal to the circumferential direction of the outer periphery portion.

5. The valve of claim 1, wherein the valve body seal surface has unevenness in a front-rear direction orthogonal to a circumferential direction of the outer periphery portion.

6. The valve of claim 1, wherein the outer periphery portion includes a return portion configured to cause the valve body seal surface to face the closing rotation direction at a trailing end position of the valve body seal surface in the closing rotation direction.

7. The valve of claim 1, wherein the housing seal surface holds a seal extending along a circumferential direction of the housing seal surface.

8. The valve of claim 1, wherein the housing includes a sealing tube having the flow path in the sealing tube, and the housing seal surface is formed on an end surface of the sealing tube.

9. The valve of claim 1, wherein the housing includes a flat portion in a vicinity of a portion that axially supports the valve body.

10. The valve of claim 9, wherein the valve body includes a hemispherical main blocker on an inner side of the outer periphery portion, and
wherein the housing includes a spherical portion, in which the main blocker of the valve body that has opened the flow path stands by, at a position adjacent to the flat portion in a circumferential direction of the housing.

11. A substrate processing apparatus comprising:
a processing container configured to accommodate and process a substrate;
an exhaust path connected to the processing container and configured to discharge a gas from the processing container; and
a valve provided in the exhaust path and configured to control a flow of the gas in the exhaust path,
wherein the valve includes:
a housing having a flow path of a fluid in the housing; and
a valve body provided rotatably with respect to the housing and configured to open and close the flow path,
wherein the housing has a housing seal surface that surrounds the flow path,
wherein the valve body has a valve body seal surface, which is formed on an outer periphery portion of the valve body and faces the housing seal surface when the valve body is located at a closing position for closing the flow path, and
wherein the valve body seal surface faces a closing rotation direction of the valve body for closing the flow path, over an entire circumference of the outer periphery portion.
